(19) United States
(12) Patent Application Publication
(10) Pub. No.: US 2026/0179878 A1
(43) Pub. Date: Jun. 25, 2026

(54) PULSE GENERATION CIRCUIT, SUBSTRATE PROCESSING APPARATUS, AND ENERGY REGENERATION METHOD

(71) Applicants: National University Corporation Kumamoto University, Kumamoto-shi (JP); Tokyo Electron Limited, Tokyo (JP)

(72) Inventors: Takashi SAKUGAWA, Miyagi (JP); Koichi NAGAMI, Kumamoto (JP)

(73) Assignees: National University Corporation Kumamoto University, Kumamoto-shi (JP); Tokyo Electron Limited, Tokyo (JP)

(21) Appl. No.: 19/536,332

(22) Filed: Feb. 11, 2026

Related U.S. Application Data
(63) Continuation of application No. PCT/JP2024/028415, filed on Aug. 8, 2024.

(30) Foreign Application Priority Data
Aug. 22, 2023 (JP) 2023-134362

(51) Int. Cl. H01J 37/32; H02M 3/335

(52) U.S. Cl. CPC H01J 37/32091; H02M 3/33523; H02M 3/33592

(57) ABSTRACT

A pulse generation circuit includes a capacitor having a first end connected to a power supply and second end connected to a ground potential, a transformer having a first end on a primary side connected to first end of the capacitor and a secondary side connected to a load, an inductor having a first end connected to a second end on the primary side of the transformer, a switching element connected between a second end of the inductor and the ground potential, a diode having a cathode connected to the second end on the primary side of the transformer and an anode connected to a ground potential, and control circuitry that controls the switching element to off in a period in which a direction of a current flowing to the primary side of the transformer is reversed after the current flows to the primary side of the transformer.

### CROSS-REFERENCE TO RELATED APPLICATIONS

This application is a continuation of International Application No. PCT/JP2024/028415, filed on Aug. 8, 2024 which claims the benefit of priority of the prior Japanese Patent Application No. 2023-134362, filed on Aug. 22, 2023, the entire contents of each are incorporated herein by reference.

### FIELD

Various aspects and embodiments of the present disclosure relate to a pulse generation circuit, a substrate processing apparatus, and an energy regeneration method.

### BACKGROUND

Japanese Laid-open Patent Publication No. H09-83052 discloses “a pulse power supply including a magnetic reset circuit that uses a saturable reactor as a magnetic switch means and supplies a reset current to a reset winding of the saturable reactor to reversely excite an iron core of the saturable reactor, wherein the magnetic reset circuit includes a DC power supply that constantly supplies the reset current to the reset winding, a first reactor that is provided at a reset current output end of the DC power supply and suppresses intrusion of a surge in a reset current path into the DC power supply, a second reactor that is provided between the first reactor and the reset winding and suppresses an induced current generated in the reset winding, and a diode that is provided in parallel with a series circuit of the second reactor and the reset winding and circulates the induced current in the second reactor”.

In addition, Japanese Laid-open Patent Publication No. 2017-153205 discloses “a snubber circuit that is provided in each of arms in a power conversion bridge circuit including at least two sets of an upper arm and a lower arm including a main switch element and suppresses a derived voltage caused by an operation of the main switch element, the snubber circuit including a regeneration circuit including a DC series circuit in which a diode and a snubber capacitor are connected in series and connected across the sets of the upper arm and the lower arm, and a snubber switch element connected between a connection point of the diode and the snubber capacitor and a connection point of the sets of the upper arm and the lower arm”.

The present disclosure provides a pulse generation circuit, a substrate processing apparatus, and an energy regeneration method capable of effectively utilizing energy.

### SUMMARY

According to an aspect of an embodiment, a pulse generation circuit includes a capacitor having a first end connected to a power supply and a second end connected to a ground potential, a transformer having a first end on a primary side connected to first end of the capacitor and a secondary side connected to a load, an inductor having a first end connected to a second end on the primary side of the transformer, a switching element connected between the second end of the inductor and the ground potential, a diode having a cathode connected to the second end on the primary side of the transformer and an anode connected to a ground potential, and a control circuitry that controls an on state and an off state of the switching element, in which the control circuitry controls the switching element to be in the on state, and controls the switching element to be in the off state in a period in which a direction of a current flowing to the primary side of the transformer is reversed after the current flows to the primary side of the transformer.

### BRIEF DESCRIPTION OF DRAWINGS

FIG. 1 is a schematic view illustrating an example of a plasma processing apparatus;

FIG. 2 is a diagram illustrating an example of a configuration of a pulse generation circuit according to the first embodiment;

FIG. 3 is a flowchart illustrating an example of an operation of a pulse generation circuit;

FIG. 4 is a timing chart illustrating an example of a change of each signal in the first embodiment;

FIG. 5 is a diagram illustrating an example of a configuration of a pulse generation circuit according to a second embodiment;

FIG. 6 is a diagram illustrating an example of a saturable inductor;

FIG. 7 is a diagram illustrating an example of a configuration of a pulse generation circuit according to a third embodiment;

FIG. 8 is a diagram illustrating an example of an excitation circuit;

FIG. 9 is a diagram illustrating an example of changes in a voltage V_{ds} and a current I_{d} in the first embodiment;

FIG. 10 is a diagram illustrating an example of changes in a voltage V_{ds} and a current I_{d} in a comparative example;

FIG. 11 is a diagram illustrating an example of changes in a voltage V_{ds} and a current I_{d} in the third embodiment;

FIG. 12 is a timing chart illustrating an example of a change of each signal in the third embodiment; and

FIG. 13 is a diagram illustrating an example of a configuration of a pulse generation circuit according to a fourth embodiment.

### DESCRIPTION OF EMBODIMENTS

Hereinafter, embodiments of a pulse generation circuit, a substrate processing apparatus, and an energy regeneration method will be described in detail with reference to the drawings. Note that the pulse generation circuit, the substrate processing apparatus, and the energy regeneration method disclosed are not limited by the following embodiments.

By the way, with the recent increase in awareness of environmental problems, power saving of devices is required. Power saving is also required in the pulse generation circuit. Therefore, the present disclosure provides a technique capable of effectively utilizing energy.

### Configuration of Plasma Processing Apparatus 1

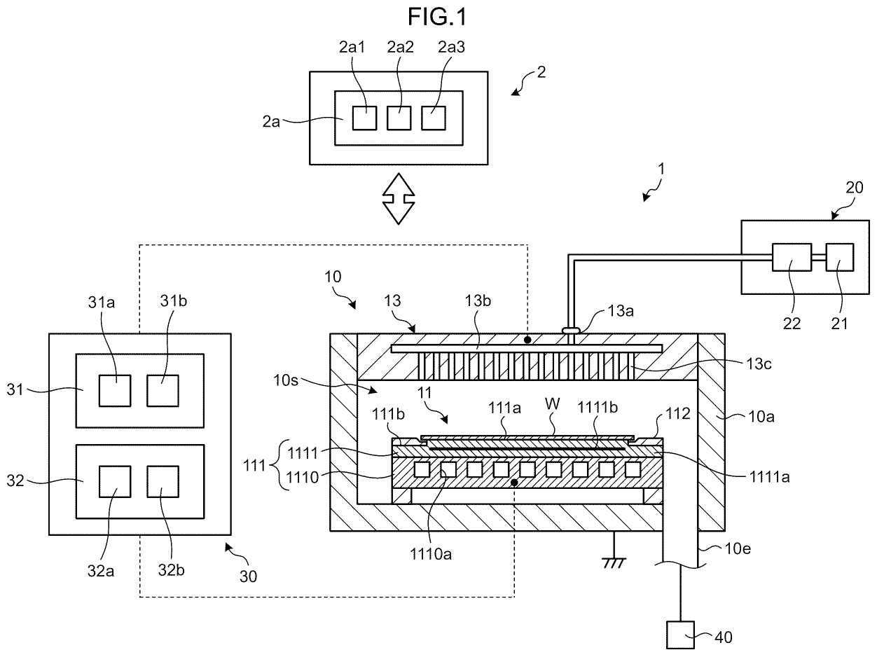

Hereinafter, a configuration example of the plasma processing system will be described. FIG. 1 is a diagram for describing a configuration example of a capacitively-coupled plasma processing apparatus 1. The plasma processing apparatus 1 is an example of a substrate processing apparatus.

The plasma processing system includes a capacitively-coupled plasma processing apparatus 1 and a controller 2. The capacitively-coupled plasma processing apparatus 1 includes a plasma processing chamber 10, a gas supply unit 20, a power supply 30, and an exhaust system 40. Further, the plasma processing apparatus 1 includes a substrate support unit 11 and a gas introduction unit. The gas introduction unit is configured to introduce at least one processing gas into the plasma processing chamber 10. The gas introduction unit includes a shower head 13. The substrate support unit 11 is disposed in the plasma processing chamber 10. The shower head 13 is disposed above the substrate support unit 11. In one embodiment, the shower head 13 constitutes at least a part of a ceiling of the plasma processing chamber 10. The plasma processing chamber 10 has a plasma processing space 10s defined by the shower head 13, a side wall 10a of the plasma processing chamber 10, and the substrate support unit 11. The plasma processing chamber 10 has at least one gas supply port for supplying at least one processing gas to the plasma processing space 10s and at least one gas discharge port for discharging the gas from the plasma processing space. The plasma processing chamber 10 is grounded. The shower head 13 and the substrate support unit 11 are electrically insulated from a case of the plasma processing chamber 10.

The substrate support unit 11 includes a main body part 111 and a ring assembly 112. The main body part 111 has a central region 111a for supporting a substrate W and an annular region 111b for supporting the ring assembly 112. The wafer is an example of the substrate W. The annular region 111b of the main body part 111 surrounds the central region 111a of the main body part 111 in plan view. The substrate W is disposed on the central region 111a of the main body part 111, and the ring assembly 112 is disposed on the annular region 111b of the main body part 111 so as to surround the substrate W on the central region 111a of the main body part 111. Therefore, the central region 111a is also referred to as a substrate support surface for supporting the substrate W, and the annular region 111b is also referred to as a ring support surface for supporting the ring assembly 112.

In one embodiment, the main body part 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has a central region 111a. In one embodiment, the ceramic member 1111a also has an annular region 111b. Note that another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled to a radio frequency (RF) power supply 31 and/or a direct current (DC) power supply 32 described later may be disposed in the ceramic member 1111a. In this case, at least one RF/DC electrode functions as a lower electrode. When a bias RF signal and/or DC signal, described below, is provided to at least one RF/DC electrode, the RF/DC electrode is also referred to as a bias electrode. Note that the conductive member of the base 1110 and at least one RF/DC electrode may function as a plurality of lower electrodes. In addition, the electrostatic electrode 1111b may function as a lower electrode. Therefore, the substrate support unit 11 includes at least one lower electrode.

The ring assembly 112 includes one or more annular members. In one embodiment, the one or more annular members include one or more edge rings and at least one covering. The edge ring is formed of a conductive material or an insulating material, and the covering is formed of an insulating material.

The substrate support unit 11 may also include a temperature control module configured to adjust at least one of the electrostatic chuck 1111, the ring assembly 112, and the substrate to a target temperature. The temperature control module may include a heater, a heat transfer fluid, a flow path 1110a, or a combination thereof. The heat transfer fluid such as brine or gas flows through the flow path 1110a. In one embodiment, the flow path 1110a is formed in the base 1110 and one or more heaters are disposed in the ceramic member 1111a of the electrostatic chuck 1111. Further, the substrate support unit 11 may include a heat transfer gas supply unit configured to supply the heat transfer gas to a gap between the back surface of the substrate W and the central region 111a.

The shower head 13 is configured to introduce at least one processing gas from the gas supply unit 20 into the plasma processing space 10s. The shower head 13 includes at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. In addition to the shower head 13, the gas introduction unit may include one or a plurality of side gas injector (SGI) attached to one or a plurality of openings formed in the side wall 10a.

The gas supply unit 20 may include at least one gas source 21 and at least one flow controller 22. In one embodiment, the gas supply unit 20 is configured to supply at least one processing gas from the respective corresponding gas source 21 to the shower head 13 via the respective corresponding flow controller 22. Each flow controller 22 may include, for example, a mass flow controller or a pressure control type flow controller. Additionally, the gas supply unit 20 may include one or more flow modulation devices that modulate or pulse the flow rate of the at least one processing gas.

The power supply 30 includes an RF power supply 31 coupled to the plasma processing chamber 10 via at least one impedance matching circuit. The RF power supply 31 is configured to provide at least one RF signal (RF power) to the at least one lower electrode and/or the at least one upper electrode. As a result, plasma is formed from at least one processing gas supplied to the plasma processing space 10s. Accordingly, the RF power supply 31 may function as at least a part of a plasma generator configured to generate plasma from one or more processing gases in the plasma processing chamber 10. In addition, by supplying the bias RF signal to at least one lower electrode, a bias potential is generated in the substrate W, and an ion component in the formed plasma can be drawn into the substrate W.

In one embodiment, the RF power supply 31 includes a first RF generator 31a and a second RF generator 31b. The first RF generator 31a is coupled to the at least one lower electrode and/or the at least one upper electrode via the at least one impedance matching circuit and is configured to generate a source RF signal (source RF power) for plasma generation. In one embodiment, the source RF signal has a frequency in a range of 10 MHz to 150 MHz. In one embodiment, the first RF generator 31a may be configured to generate a plurality of source RF signals having different frequencies. The generated one or more source RF signals are provided to the at least one lower electrode and/or the at least one upper electrode.

The second RF generator 31b is coupled to the at least one lower electrode via the at least one impedance matching circuit and configured to generate a bias RF signal (bias RF power). The frequency of the bias RF signal may be the same as or different from the frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are provided to the at least one lower electrode. Also, in various embodiments, at least one of the source RF signal and the bias RF signal may be pulsed.

The power supply 30 may also include a DC power supply 32 coupled to the plasma processing chamber 10. The DC power supply 32 includes a first DC generator 32a and a second DC generator 32b. In an embodiment, the first DC generator 32a is connected to the at least one lower electrode and configured to generate the first DC signal. The generated first bias DC signal is applied to the at least one lower electrode. In an embodiment, the second DC generator 32b is connected to the at least one upper electrode and configured to generate the second DC signal. The generated second DC signal is applied to the at least one upper electrode.

In the present embodiment, at least one of the first and second DC signals is pulsed. A sequence of voltage pulses is applied to the at least one lower electrode and/or the at least one upper electrode. The voltage pulse may have a pulse waveform of a rectangle, a trapezoid, a triangle, or a combination thereof. In the present embodiment, a pulse generation circuit for generating a sequence of voltage pulses from the DC signal is connected between the first DC generator 32a and the at least one lower electrode. Therefore, the first DC generator 32a and the pulse generation circuit constitute a voltage pulse generator. In a case where the second DC generator 32b and the pulse generation circuit constitute the voltage pulse generator, the voltage pulse generator is connected to at least one upper electrode. The voltage pulse may have a positive polarity or a negative polarity. The sequence of voltage pulses may also include one or a plurality of positive voltage pulses and one or a plurality of negative voltage pulses within one period. Note that the first and second DC generators 32a and 32b may be provided in addition to the RF power supply 31, and the first DC generator 32a may be provided instead of the second RF generator 31b.

The exhaust system 40 can be connected to a gas discharge port 10e provided, for example, at the bottom part of the plasma processing chamber 10. The exhaust system 40 may include a pressure regulation valve and a vacuum pump. The pressure in the plasma processing space 10s is adjusted by the pressure regulation valve. The vacuum pump may include a turbomolecular pump, a dry pump, or a combination thereof.

The controller 2 processes a computer-executable command that causes the plasma processing apparatus 1 to execute the various steps described in the present disclosure. The controller 2 can be configured to control each element of the plasma processing apparatus 1 so as to execute various steps described herein. In one embodiment, a part or the entirety of the controller 2 may be included in the plasma processing apparatus 1. The controller 2 may include a processing unit 2a1, a storage unit 2a2, and a communication interface 2a3. The controller 2 is realized by, for example, a computer 2a. The processing unit 2a1 can be configured to perform various control operations by reading a program from the storage unit 2a2 and executing the read program. This program may be stored in the storage unit 2a2 in advance, or may be acquired via a medium when necessary. The acquired program is stored in the storage unit 2a2, and is read from the storage unit 2a2 and executed by the processing unit 2a1. The medium may be various storage media readable by the computer 2a, or may be a communication line connected to the communication interface 2a3. The processing unit 2a1 may be a central processing unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICS (“Application Specific Integrated Circuits”), FPGAS (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

### First Embodiment

### Configuration of Pulse Generation Circuit 50

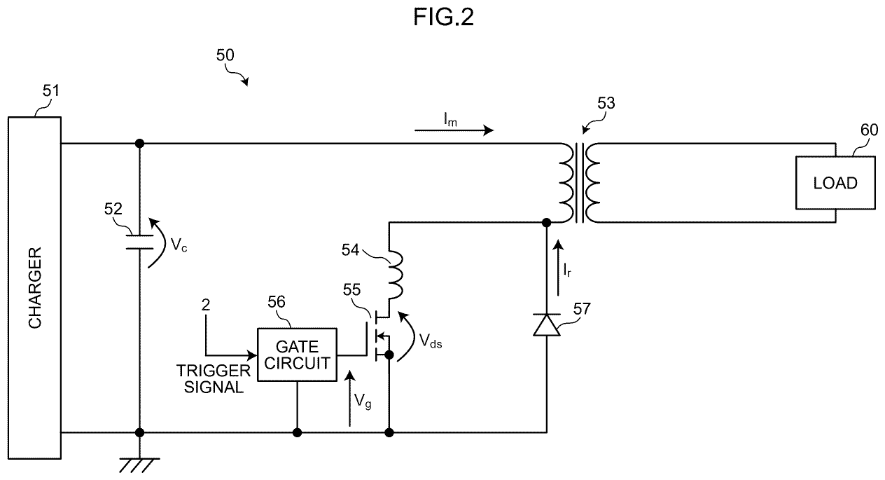

FIG. 2 is a diagram illustrating an example of a configuration of a pulse generation circuit 50 according to the first embodiment. The pulse generation circuit 50 in the present embodiment includes a capacitor 52, a transformer 53, an inductor 54, a switching element 55, a gate circuit 56, and a diode 57. The controller 2 and the gate circuit 56 are examples of the control circuitry.

The capacitor 52 has one end connected to a charger 51 and the other end connected to a ground potential. The charger 51 is an example of a power supply. Charging of the capacitor 52 by the charger 51 is controlled by the controller 2. The voltage of the capacitor 52 is defined as V_{c}. In the transformer 53, one end on the primary side is connected to one end of the capacitor 52, and the secondary side is connected to the load 60. The current flowing from the capacitor 52 to the transformer 53 is defined as Iₘ. One end of the inductor 54 is connected to the other end on the primary side of the transformer 53.

The switching element 55 is connected between the other end of the inductor 54 and the ground potential. In the present embodiment, the switching element 55 is an n-channel MOSFET. The switching element 55 is preferably a MOSFET using silicon carbide. The switching element 55 may be a p-channel MOSFET or an IGBT.

The gate circuit 56 outputs a gate voltage V_{g} for controlling on and off of the switching element 55 according to a trigger signal output from the controller 2. In the present embodiment, the switching element 55 is turned on when the gate voltage V_{g} is high, and the switching element 55 is turned off when the gate voltage V_{g} is low. A delay ΔT_{g} exists between the trigger signal input from the controller 2 to the gate circuit 56 and the gate voltage V_{g} output from the gate circuit 56 to the switching element 55.

The cathode of the diode 57 is connected to the other end on the primary side of the transformer 53, and the anode of the diode 57 is connected to the ground potential. The current flowing from the diode 57 to the transformer 53 is defined as Iᵣ. The diode 57 is preferably a diode that operates at a high speed and has excellent reverse recovery characteristics. For example, the diode 57 is preferably a fast recovery diode or a Schottky barrier diode.

### Operation of Pulse Generation Circuit 50

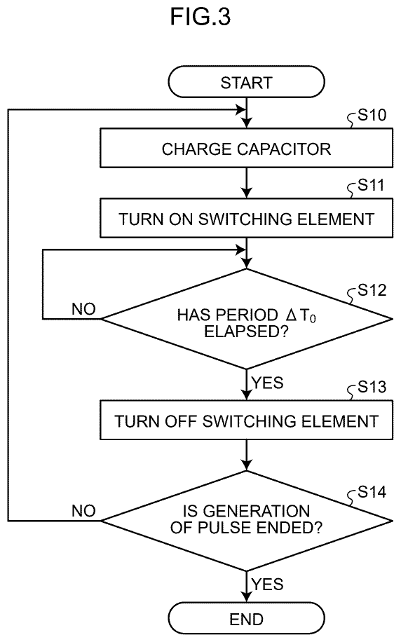

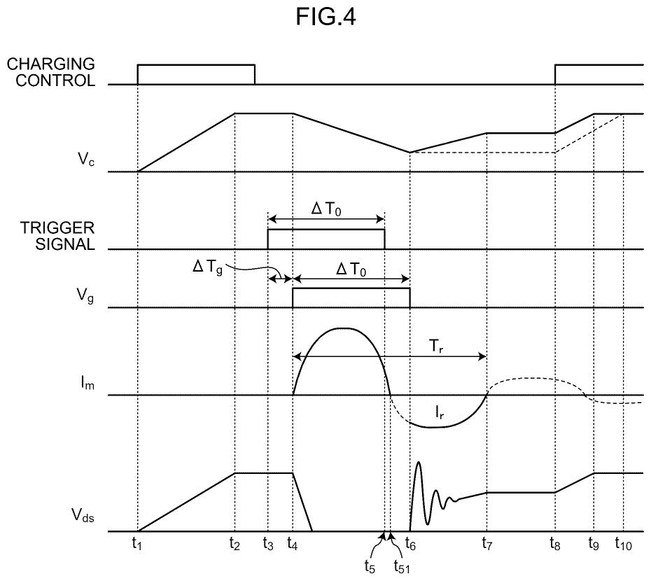

FIG. 3 is a flowchart illustrating an example of the operation of the pulse generation circuit 50. Each processing illustrated in FIG. 3 is realized by the controller 2 controlling each unit of the pulse generation circuit 50. Hereinafter, a description will be given with reference to the timing chart illustrated in FIG. 4. Note that before the start of the flowchart illustrated in FIG. 3, the switching element 55 is controlled to be in the off state.

First, the charger 51 is controlled to charge the capacitor 52 (Step S10). In Step S10, for example, the charger 51 starts charging the capacitor 52 at timing t₁ illustrated in FIG. 4. Then, at timing t₂ when the voltage V_{c} of the capacitor 52 reaches a predetermined voltage, charging of the capacitor 52 by the charger 51 is stopped. In addition, since the switching element 55 is controlled to be in the off state, the drain-source voltage V_{ds} of the switching element 55 also increases together with the voltage V_{c} to a predetermined voltage from the timing t₁ to the timing t₂.

Next, the switching element 55 is controlled to be in an on state (Step S11). Step S11 is an example of step a). In Step S11, for example, at timing t₃ illustrated in FIG. 4, a trigger signal instructing the on state of the switching element 55 is supplied from the controller 2 to the gate circuit 56. The gate circuit 56 applies the high gate voltage V_{g} to the gate terminal of the switching element 55 at timing t₄ when the delay ΔT_{g} has elapsed from the start of the supply of the trigger signal. When the high gate voltage V_{g} is applied to the gate terminal, the switching element 55 is controlled to be in the on state. As a result, for example, as illustrated in FIG. 4, the current Iₘ flows from the capacitor 52 via the transformer 53, the inductor 54, and the switching element 55. In addition, the voltage V_{ds} of the switching element 55 becomes substantially 0.

Here, the current Iₘ attenuates while vibrating at a resonance frequency caused by the capacitance of the capacitor 52, the inductance of the transformer 53, the inductance of the inductor 54, the parasitic capacitance of the wiring, and the parasitic inductance of the wiring. A period Tᵣ illustrated in FIG. 4 indicates a resonance period of the current Iₘ.

Next, it is judged whether a predetermined period ΔT₀ has elapsed from the start of the supply of the trigger signal (Step S12). When the predetermined period ΔT₀ has not elapsed from the start of the supply of the trigger signal (Step S12: No), the processing illustrated in Step S12 is executed again.

Meanwhile, when the predetermined period ΔT₀ has elapsed from the start of the supply of the trigger signal (Step S12: Yes), the switching element 55 is controlled to be in the off state (Step S13). Steps S12 and S13 are examples of step b). In Step S13, for example, at timing t₅ illustrated in FIG. 4, the trigger signal instructing the off state of the switching element 55 is supplied from the controller 2 to the gate circuit 56. The gate circuit 56 applies the low gate voltage V_{g} to the gate terminal of the switching element 55 at timing t₆ when the delay ΔT_{g} has elapsed since the supply of the trigger signal instructing the off state is started. When the low gate voltage V_{g} is applied to the gate terminal, the switching element 55 is controlled to be in the off state. At this time, an off-surge occurs in the switching element 55, and the voltage V_{ds} greatly vibrates.

Next, it is judged whether or not to end the generation of the pulse (Step S14). When the generation of the pulse is not ended (Step S14: No), the processing illustrated in Step S10 is executed again. Meanwhile, when the generation of the pulse is ended (Step S14: Yes), the processing illustrated in this flowchart is ended.

In the present embodiment, the timing t₆ at which the switching element 55 is controlled to be in the off state is timing between timing at which the direction of the current Iₘ attenuating while vibrating first inverts and timing at which the direction of the current Iₘ returns to the original direction again. That is, the timing t₆ is timing between timing t₅₁ at which the direction of the current Iₘ first inverts and timing t₇ at which the direction of the current Iₘ first returns to the original direction. In other words, the length of the period ΔT₀ of the trigger signal indicating the on state of the switching element 55 is longer than ½ of the resonance period Tᵣ and shorter than the resonance period Tᵣ. As a result, the regenerative current Iᵣ flows through the diode 57, and the capacitor 52 is recharged by the regenerative current Iᵣ. As a result, for example, as illustrated in FIG. 4, the capacitor 52 is charged in a period from timing t₆ to t₇ at which charging by the charger 51 is not performed, and the voltage V_{c} of the capacitor 52 increases. Accordingly, energy can be effectively used.

Note that the timing t₆ at which the switching element 55 is controlled to be in the off state is preferably timing close to the timing t₅₁ at which the direction of the current Iₘ first inverts between the timing t₅ at which the direction of the current Iₘ first inverts and the timing t at which the direction of the current Iₘ first returns to the original direction. As a result, more regenerative current Iᵣ can be used for charging the capacitor 52.

Here, in a case where the diode 57 is not provided between the transformer 53 and the switching element 55, when the switching element 55 is controlled to be in the off state, the regenerative current Iᵣ does not flow. Therefore, the voltage V_{c} of the capacitor 52 after the switching element 55 is controlled to be in the off state at the timing t₆ is maintained at the voltage at the timing t₆, for example, as indicated by a broken line in FIG. 4. Therefore, in a case where the charging of the capacitor 52 by the charger 51 is resumed at timing t₈, the voltage V_{c} of the capacitor 52 gradually increases and becomes a predetermined voltage at timing t₁₀, for example, as indicated by a broken line in FIG. 4.

Meanwhile, in the present embodiment, since the diode 57 is provided between the transformer 53 and the switching element 55, the regenerative current Iᵣ flows through the diode 57, and the capacitor 52 is charged by the regenerative current Iᵣ. Then, in a case where the charging of the capacitor 52 by the charger 51 is resumed at the timing t₈, since a certain amount of charge is accumulated in the capacitor 52, the voltage V_{c} of the capacitor 52 increases more quickly to a predetermined voltage. In the example of FIG. 4, the voltage V_{c} of the capacitor 52 in the present embodiment reaches a predetermined voltage at timing t₉ earlier than the timing t₁₀. As a result, the next pulse can be output more quickly.

In the example of FIG. 4, the capacitor 52 is charged by the regenerative current Iᵣ in the period in which the direction of the current Iₘ is first reversed, but the regenerative current Iᵣ also flows in the period in which the direction of the current Iₘ is reversed for the second and subsequent times. Therefore, by providing the diode 57, the capacitor 52 can be charged with the regenerative current Iᵣ in the period in which the direction of the current Iₘ is reversed after the switching element 55 is controlled to be in the off state. As a result, energy can be effectively used.

The first embodiment has been described above. As described above, the pulse generation circuit (pulse generation circuit 50) in the present embodiment includes the capacitor (capacitor 52) having one end connected to the power supply (charger 51) and the other end connected to the ground potential, the transformer (transformer 53) having one end on the primary side connected to one end of the capacitor and the secondary side connected to the load (load 60), the inductor (inductor 54) having one end connected to the other end on the primary side of the transformer, the switching element (switching element 55) connected between the other end of the inductor and the ground potential, the diode (diode 57) having the cathode connected to the other end on the primary side of the transformer and the anode connected to the ground potential, and the control circuitry (controller 2 and gate circuit 56) that controls the on state and the off state of the switching element, in which the control circuitry controls the switching element to be in the on state and controls the switching element to be in the off state in a period in which a direction of a current flowing to the primary side of the transformer is reversed after the current flows to the primary side of the transformer. Accordingly, energy can be effectively used.

In the above embodiment, the switching element is a MOSFET. The switching element may be a MOSFET using silicon carbide. This enables high-speed switching.

In addition, the diode in the above-described embodiment is a fast recovery diode or a Schottky barrier diode. As a result, the regenerative current can quickly flow to the capacitor.

In addition, the substrate processing apparatus according to the above-described embodiment includes the chamber (plasma processing chamber 10) that has the gas supply port (gas supply port 13a) and the gas exhaust port (gas discharge port 10e) and accommodates the substrate (substrate W), and the pulse generation circuit (pulse generation circuit 50) that performs processing of the substrate using plasma by converting a gas supplied through the gas supply port into plasma in the chamber by supplying electric power that changes in a pulse shape into the chamber. The pulse generation circuit includes the capacitor (capacitor 52) having one end connected to the power supply (charger 51) and the other end connected to the ground potential, the transformer (transformer 53) having one end on the primary side connected to one end of the capacitor and the secondary side connected to the load (load 60), the inductor (inductor 54) having one end connected to the other end on the primary side of the transformer, the switching element (switching element 55) connected between the other end of the inductor and the ground potential, the diode (diode 57) having the cathode connected to the other end on the primary side of the transformer and the anode connected to the ground potential, and the control circuitry (controller 2 and gate circuit 56) that controls the on state and the off state of the switching element, in which the control circuitry controls the switching element to be in the on state and controls the switching element to be in the off state in a period in which a direction of a current flowing to the primary side of the transformer is reversed after the current flows to the primary side of the transformer. Accordingly, energy can be effectively used.

In addition, in the energy regeneration method in the above-described embodiment, in the pulse generation circuit (pulse generation circuit 50) including the capacitor (capacitor 52) having one end connected to the power supply (charger 51) and the other end connected to the ground potential, the transformer (transformer 53) having one end on the primary side connected to one end of the capacitor and the secondary side connected to the load (load 60), the inductor (inductor 54) having one end connected to the other end on the primary side of the transformer, the switching element (switching element 55) connected between the other end of the inductor and the ground potential, the diode (diode 57) having the cathode connected to the other end on the primary side of the transformer and the anode connected to the ground potential, and the control circuitry (controller 2 and gate circuit 56) that controls the on state and the off state of the switching element, the control circuitry executes the step a) and step b). In the step a), the switching element is controlled to be in the on state. In the step b), after the current flows to the primary side of the transformer by the switching element being in the on state, the switching element is controlled to be in the off state in the period in which the direction of the current flowing to the primary side of the transformer is reversed. Accordingly, energy can be effectively used.

### Second Embodiment

In the first embodiment, the inductor 54 is provided in the pulse generation circuit 50, but the second embodiment is different from the first embodiment in that a saturable inductor 54′ is provided instead of the inductor 54. Hereinafter, differences from the first embodiment will be mainly described.

### Configuration of Pulse Generation Circuit 50

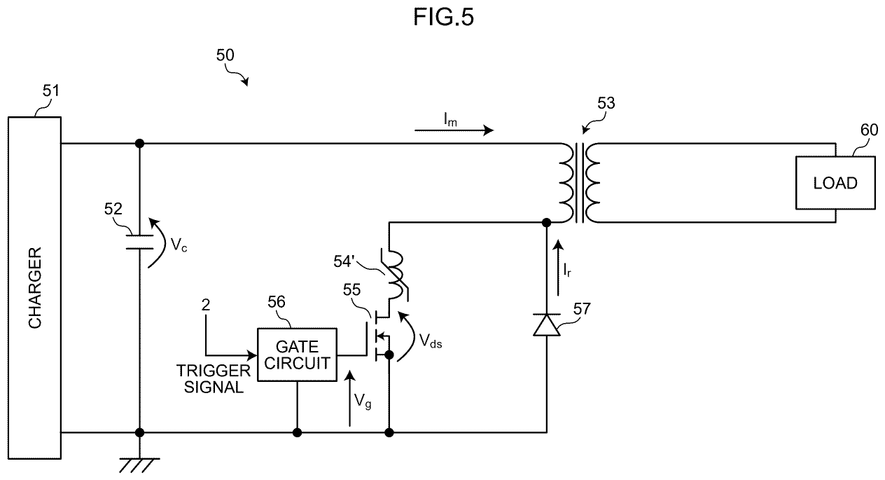

FIG. 5 is a diagram illustrating an example of a configuration of a pulse generation circuit 50 according to the second embodiment. The pulse generation circuit 50 in the present embodiment includes a capacitor 52, a transformer 53, the saturable inductor 54′, a switching element 55, a gate circuit 56, and a diode 57. One end of the saturable inductor 54′ is connected to the other end on the primary side of the transformer 53, and the other end is grounded via the switching element 55.

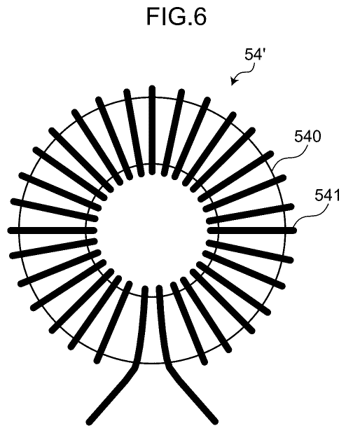

The saturable inductor 54′ has a structure in which an electric wire is wound around a core such as ferrite or a cobalt-based amorphous alloy. Specifically, as illustrated in FIG. 6, for example, the saturable inductor 54′ is a toroidal coil in which the electric wire 541 is wound around an annular toroidal core 540. By providing the saturable inductor 54′ instead of the inductor 54, the switching loss of the switching element 55 can be reduced.

### Third Embodiment

The third embodiment is different from the second embodiment in that an excitation circuit 58 for exciting the saturable inductor 54′ is further provided. Hereinafter, differences from the second embodiment will be mainly described.

### Configuration of Pulse Generation Circuit 50

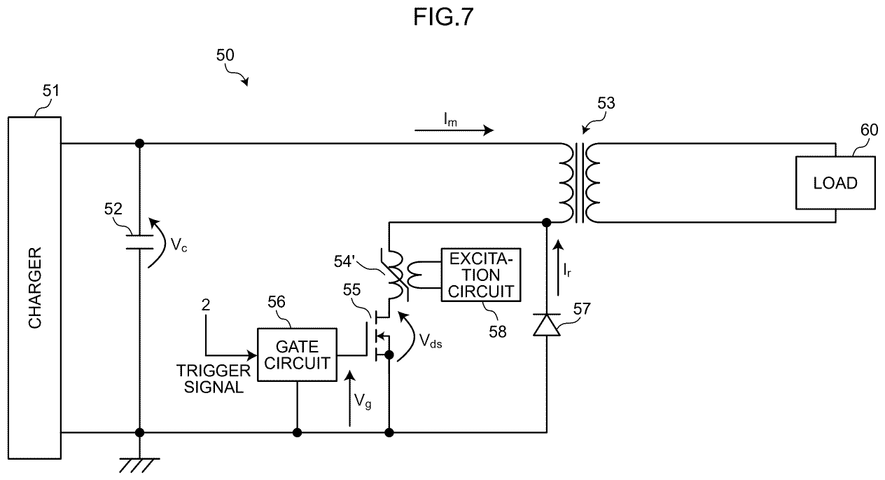

FIG. 7 is a diagram illustrating an example of a configuration of a pulse generation circuit 50 according to the third embodiment. The pulse generation circuit 50 in the present embodiment includes a capacitor 52, a transformer 53, a saturable inductor 54′, a switching element 55, a gate circuit 56, a diode 57, and the excitation circuit 58. The excitation circuit 58 excites the saturable inductor 54′ so as to generate a magnetic field in a direction opposite to the magnetic field generated by the current flowing through the saturable inductor 54′ when the switching element 55 is turned on.

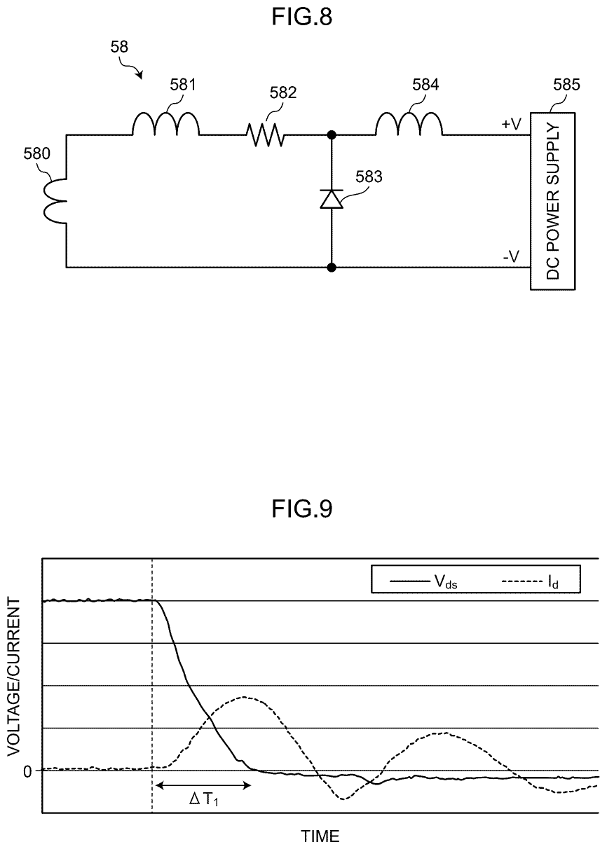

FIG. 8 is a diagram illustrating an example of the excitation circuit 58. The excitation circuit 58 includes an inductor 580, an inductor 581, a resistor 582, a diode 583, an inductor 584, and a DC power supply 585. The inductor 581, the resistor 582, and the inductor 584 are connected in series between the + side of the DC power supply 585 and one end of the inductor 580. The other end of the inductor 580 is connected to the negative side of the DC power supply 585. A cathode of the diode 583 is connected to a node between the resistor 582 and the inductor 584, and an anode of the diode 583 is connected to a negative side of the DC power supply 585.

The magnetic field generated in the inductor 580 by the current supplied from the DC power supply 585 to the inductor 580 via the inductor 584, the resistor 582, and the inductor 581 excites the saturable inductor 54′. As a result, when the switching element 55 transitions to the on state, it is possible to lengthen the time required for the magnetic flux density of the saturable inductor 54′ to be saturated. As a result, the rise of the current I_{d} of the switching element 55 can be delayed. In addition, since the impedance of the saturable inductor 54′ can be maintained high until the magnetic flux density is saturated, the voltage V_{ds} of the switching element 55 can be quickly lowered.

Here, the voltage V_{ds} and the current I_{d} in the switching element 55 of the first embodiment change as illustrated in FIG. 9, for example. FIG. 9 is a diagram illustrating an example of changes in the voltage V_{ds} and the current I_{d} in the first embodiment. In the example of FIG. 9, the fall of the voltage V_{ds} and the rise of the current I_{d} overlap in the period ΔT₁.

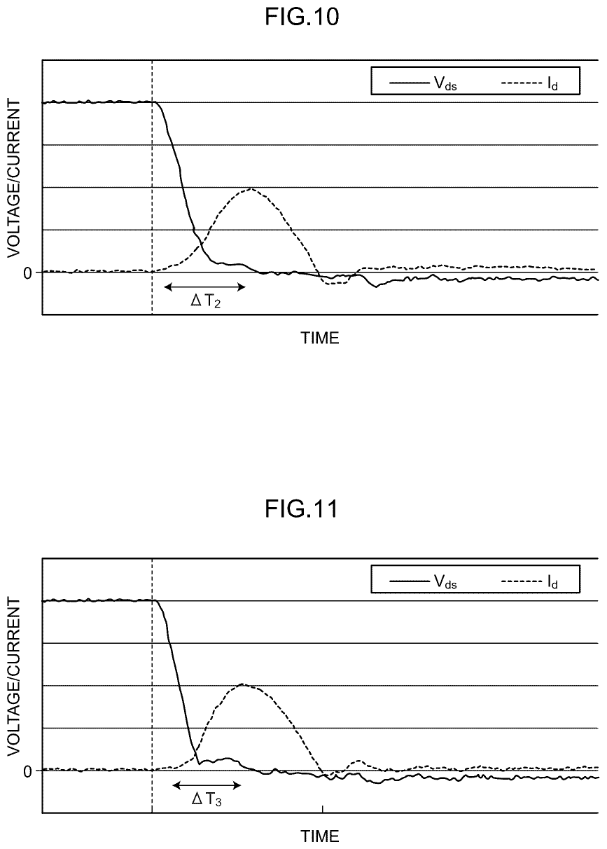

FIG. 10 is a diagram illustrating an example of changes in the voltage V_{ds} and the current I_{d} in the comparative example. In the comparative example, a solenoid coil in which an electric wire is wound around a rod-shaped core such as ferrite is used instead of the inductor 54. In the example of FIG. 10, the fall of the voltage V_{ds} and the rise of the current I_{d} overlap in the period ΔT₂. Comparing FIG. 9 with FIG. 10, the overlap between the fall of the voltage V_{ds} and the rise of the current I_{d} is smaller in the comparative example than in the first embodiment. That is, the switching loss is smaller in the comparative example than in the first embodiment.

FIG. 11 is a diagram illustrating an example of changes in the voltage V_{ds} and the current I_{d} in the third embodiment. In the third embodiment, a toroidal coil in which an electric wire is wound around a core such as ferrite is used as the saturable inductor 54′. In the example of FIG. 11, the fall of the voltage V_{ds} and the rise of the current I_{d} overlap in the period ΔT₃. Comparing FIGS. 9 to 11, the overlapping between the fall of the voltage V_{ds} and the rise of the current I_{d} is the smallest in the third embodiment. That is, among the first embodiment, the comparative example, and the third embodiment, the switching loss of the third embodiment is the smallest.

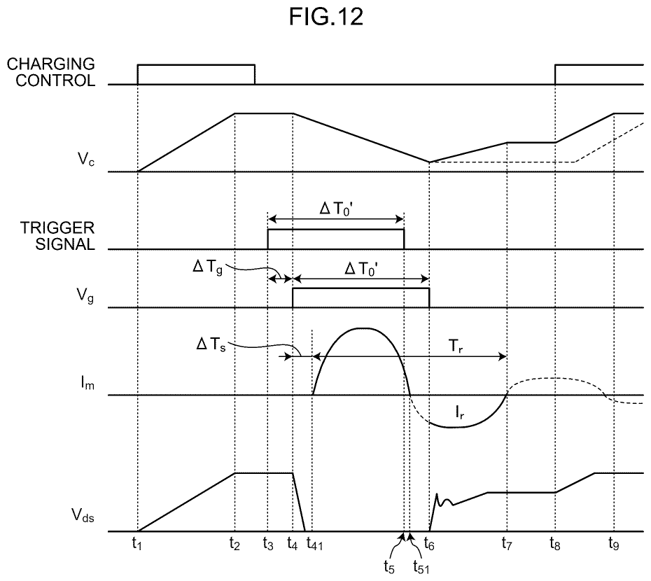

FIG. 12 is a timing chart illustrating an example of a change of each signal in the third embodiment. Hereinafter, a description will be given focusing on portions different from those in FIG. 4.

The gate circuit 56 applies a high gate voltage V_{g} to the gate terminal of the switching element 55 at the timing t₄ at which the delay ΔT_{g} has elapsed from the timing t₃ at which the supply of the trigger signal is started. By applying the high gate voltage V_{g} to the gate terminal, the switching element 55 is controlled to be in the on state, and the current starts to flow through the saturable inductor 54′. However, in the period of ATs until the magnetic flux density of the core of the saturable inductor 54′ is saturated, the impedance of the saturable inductor 54′ is high impedance, and thus the current I_{d} does not flow in the switching element 55. Therefore, the rise of the current Iₘ is delayed by the period ΔTₛ, and the current Iₘ starts to flow from timing t₄₁, for example.

Furthermore, at the timing t₆, when the low gate voltage V_{g} is applied to the gate terminal of the switching element 55 and the switching element 55 is controlled to be in the off state, an off-surge occurs in the switching element 55. However, in the present embodiment, the saturable inductor 54′ is connected to the switching element 55. Therefore, the fluctuation of the voltage V_{ds} due to the off-surge is suppressed to be low as compared with the pulse generation circuit 50 of the first embodiment in which the inductor 54 is connected to the switching element 55 (see FIGS. 4 and 12). As a result, it is possible to prevent the switching element 55 from being damaged due to the off-surge.

### Fourth Embodiment

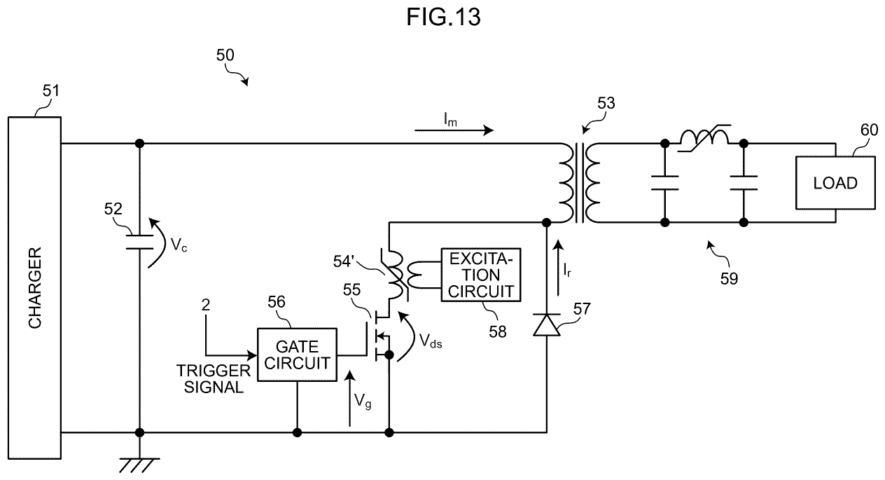

In the fourth embodiment, for example, as illustrated in FIG. 13, a magnetic pulse compression circuit 59 is provided between the transformer 53 and the load 60. As a result, the width of the pulse supplied to the load 60 can be narrowed. In the example of FIG. 13, one magnetic pulse compression circuit 59 is provided between the transformer 53 and the load, but the disclosed technology is not limited thereto, and a plurality of magnetic pulse compression circuits 59 may be provided between the transformer 53 and the load.

### Others

Note that the technology disclosed in the present application is not limited to the above-described embodiments, and various modifications can be made within the scope of the gist of the technology.

For example, in the above-described embodiment, the plasma processing apparatus 1 that performs processing using capacitively-coupled plasma (CCP) has been described as an example of the plasma source, but the plasma source is not limited thereto. Examples of the plasma source other than the capacitively-coupled plasma include inductively coupled plasma (ICP), microwave-excited surface wave plasma (SWP), electron cyclotron resonance plasma (ECP), helicon wave-excited plasma (HWP), and the like.

It should be understood that the embodiment disclosed herein is illustrative in all respects and is not restrictive. Indeed, the embodiments described above may be embodied in various forms. The above embodiments may be omitted, replaced, or modified in various forms without departing from the scope and spirit of the appended claims.

According to various aspects and embodiments of the present disclosure, energy can be effectively utilized.

In addition, regarding the above embodiments, the following Supplementary Notes are further disclosed. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

### (Supplementary Note 1)

A pulse generation circuit including:
a capacitor having a first end connected to a power supply and a second end connected to a ground potential;
a transformer having a first end on a primary side connected to a first end of the capacitor and a secondary side connected to a load;
an inductor having a first end connected to a second end on the primary side of the transformer;
a switching element connected between a second end of the inductor and the ground potential;
a diode having a cathode connected to the second end on the primary side of the transformer and an anode connected to a ground potential; and
control circuitry that controls an on state and an off state of the switching element,
in which the control circuitry controls the switching element to be in the on state, and controls the switching element to be in the off state in a period in which a direction of a current flowing to the primary side of the transformer is reversed after the current flows to the primary side of the transformer.

### (Supplementary Note 2)

The pulse generation circuit according to Supplementary Note 1, in which the inductor is a saturable inductor.

### (Supplementary Note 3)

The pulse generation circuit according to Supplementary Note 2, further including an excitation circuit that excites the saturable inductor to generate a magnetic field in a direction opposite to a magnetic field generated by a current flowing through the saturable inductor when the switching element is turned on.

### (Supplementary Note 4)

The pulse generation circuit according to Supplementary Note 2 or 3, in which the inductor is a toroidal coil in which an electric wire is wound around an annular core.

### (Supplementary Note 5)

The pulse generation circuit according to any one of Supplementary Notes 1 to 4, in which the switching element is a MOSFET.

### (Supplementary Note 6)

The pulse generation circuit according to Supplementary Note 5, in which the switching element is a MOSFET using silicon carbide.

### (Supplementary Note 7)

The pulse generation circuit according to any one of Supplementary Notes 1 to 6, in which the diode is a fast recovery diode or a Schottky barrier diode.

### (Supplementary Note 8)

The pulse generation circuit according to any one of Supplementary Notes 1 to 7, further including a magnetic pulse compression circuit provided between the secondary side of the transformer and the load.

### (Supplementary Note 9)

A substrate processing apparatus including:
a chamber having a gas supply port and a gas exhaust port and accommodating a substrate; and
a pulse generation circuit that performs processing of the substrate using plasma by forming a gas supplied through the gas supply port into plasma in the chamber by supplying electric power that changes in a pulse shape into the chamber,
in which the pulse generation circuit includes
a capacitor having a first end connected to a power supply and a second end connected to a ground potential,
a transformer having a first end on a primary side connected to the first end of the capacitor and a secondary side connected to a load,
an inductor having a first end connected to a second end on the primary side of the transformer,
a switching element connected between a second end of the inductor and the ground potential,
a diode having a cathode connected to the second end on the primary side of the transformer and an anode connected to a ground potential, and
control circuitry that controls an on state and an off state of the switching element, and
the control circuitry controls the switching element to be in the on state, and controls the switching element to be in the off state in a period in which a direction of a current flowing to the primary side of the transformer is reversed after the current flows to the primary side of the transformer.

### (Supplementary Note 10)

The substrate processing apparatus according to Supplementary Note 9, wherein the inductor is a saturable inductor.

### (Supplementary Note 11)

The substrate processing apparatus according to Supplementary Note 10, further comprising an excitation circuit that excites the saturable inductor to generate a magnetic field in a direction opposite to a magnetic field generated by a current flowing through the saturable inductor when the switching element is turned on.

### (Supplementary Note 12)

The substrate processing apparatus according to Supplementary Note 10, wherein the inductor is a toroidal coil in which an electric wire is wound around an annular core.

### (Supplementary Note 13)

The substrate processing apparatus according to Supplementary Note 9, wherein the switching element is a MOSFET.

### (Supplementary Note 14)

The substrate processing apparatus according to Supplementary Note 13, wherein the switching element is a MOSFET using silicon carbide.

### (Supplementary Note 15)

The substrate processing apparatus according to Supplementary Note 9, wherein the diode is a fast recovery diode or a Schottky barrier diode.

### (Supplementary Note 16)

The substrate processing apparatus according to Supplementary Note 9, further comprising a magnetic pulse compression circuit provided between the secondary side of the transformer and the load.

### (Supplementary Note 17)

An energy regeneration method in a pulse generation circuit including
a capacitor having a first end connected to a power supply and a second end connected to a ground potential,
a transformer having a first end on a primary side connected to the first end of the capacitor and a secondary side connected to a load,
an inductor having a first end connected to a second end on the primary side of the transformer,
a switching element connected between a second end of the inductor and the ground potential, and
a diode having a cathode connected to the second end on the primary side of the transformer and an anode connected to a ground potential, and
control circuitry, the method comprising, by the control circuitry:
a) controlling the switching element to be in an on state; and
b) controlling the switching element to be in an off state in a period in which a direction of a current flowing to the primary side of the transformer is reversed after the current flows to the primary side of the transformer by the switching element being in the on state.

### (Supplementary Note 18)

The energy regeneration method according to Supplementary Note 17, further comprising, by the control circuitry:
c) determining whether a predetermined period has elapsed after a), and
in response to the predetermined period not elapsing, re-executing step c).

### (Supplementary Note 19)

The energy regeneration method according to Supplementary Note 18, wherein step b) is performed after determining the predetermined period has elapsed.

### (Supplementary Note 20)

The energy regeneration method according to Supplementary Note 17, wherein in step a), an excitation circuit excites the inductor to generate a magnetic field in a direction opposite to a magnetic field generated by a current flowing through the inductor.

What is claimed is:

1. A pulse generation circuit comprising:
a capacitor having a first end connected to a power supply and a second end connected to a ground potential;
a transformer having a first end on a primary side connected to the first end of the capacitor and a secondary side connected to a load;
an inductor having a first end connected to a second end on the primary side of the transformer;
a switching element connected between a second end of the inductor and the ground potential;
a diode having a cathode connected to the second end on the primary side of the transformer and an anode connected to a ground potential; and
control circuitry that controls an on state and an off state of the switching element,
wherein the control circuitry controls the switching element to be in the on state, and controls the switching element to be in the off state in a period in which a direction of a current flowing to the primary side of the transformer is reversed after the current flows to the primary side of the transformer.

2. The pulse generation circuit according to claim 1, wherein the inductor is a saturable inductor.

3. The pulse generation circuit according to claim 2, further comprising an excitation circuit that excites the saturable inductor to generate a magnetic field in a direction opposite to a magnetic field generated by a current flowing through the saturable inductor when the switching element is turned on.

4. The pulse generation circuit according to claim 2, wherein the inductor is a toroidal coil in which an electric wire is wound around an annular core.

5. The pulse generation circuit according to claim 1, wherein the switching element is a MOSFET.

6. The pulse generation circuit according to claim 5, wherein the switching element is a MOSFET using silicon carbide.

7. The pulse generation circuit according to claim 1, wherein the diode is a fast recovery diode or a Schottky barrier diode.

8. The pulse generation circuit according to claim 1, further comprising a magnetic pulse compression circuit provided between the secondary side of the transformer and the load.

9. A substrate processing apparatus comprising:
a chamber having a gas supply port and a gas exhaust port and accommodating a substrate; and
a pulse generation circuit that performs processing of the substrate using plasma by forming a gas supplied through the gas supply port into plasma in the chamber by supplying electric power that changes in a pulse shape into the chamber,
wherein the pulse generation circuit includes
a capacitor having a first end connected to a power supply and a second end connected to a ground potential,
a transformer having a first end on a primary side connected to the first end of the capacitor and a secondary side connected to a load,
an inductor having a first end connected to a second end on the primary side of the transformer,
a switching element connected between a second end of the inductor and the ground potential,
a diode having a cathode connected to the second end on the primary side of the transformer and an anode connected to a ground potential, and
control circuitry that controls an on state and an off state of the switching element, and
the control circuitry controls the switching element to be in the on state, and controls the switching element to be in the off state in a period in which a direction of a current flowing to the primary side of the transformer is reversed after the current flows to the primary side of the transformer.

10. The substrate processing apparatus according to claim 9, wherein the inductor is a saturable inductor.

11. The substrate processing apparatus according to claim 10, further comprising an excitation circuit that excites the saturable inductor to generate a magnetic field in a direction opposite to a magnetic field generated by a current flowing through the saturable inductor when the switching element is turned on.

12. The substrate processing apparatus according to claim 10, wherein the inductor is a toroidal coil in which an electric wire is wound around an annular core.

13. The substrate processing apparatus according to claim 9, wherein the switching element is a MOSFET.

14. The substrate processing apparatus according to claim 13, wherein the switching element is a MOSFET using silicon carbide.

15. The substrate processing apparatus according to claim 9, wherein the diode is a fast recovery diode or a Schottky barrier diode.

16. The substrate processing apparatus according to claim 9, further comprising a magnetic pulse compression circuit provided between the secondary side of the transformer and the load.

17. An energy regeneration method in a pulse generation circuit including:
a capacitor having a first end connected to a power supply and a second end connected to a ground potential,
a transformer having a first end on a primary side connected to a first end of the capacitor and a secondary side connected to a load,
an inductor having a first end connected to a second end on the primary side of the transformer,
a switching element connected between a second end of the inductor and the ground potential, and
a diode having a cathode connected to the second end on the primary side of the transformer and an anode connected to a ground potential, and
control circuitry, the method comprising, by the control circuitry: a) controlling the switching element to be in an on state; and
b) controlling the switching element to be in an off state in a period in which a direction of a current flowing to the primary side of the transformer is reversed after the current flows to the primary side of the transformer by the switching element being in the on state.

18. The energy regeneration method according to claim 17, further comprising, by the control circuitry:
c) determining whether a predetermined period has elapsed after a), and
in response to the predetermined period not elapsing, re-executing step c).

19. The energy regeneration method according to claim 18, wherein step b) is performed after determining the predetermined period has elapsed.

20. The energy regeneration method according to claim 17, wherein in step a), an excitation circuit excites the inductor to generate a magnetic field in a direction opposite to a magnetic field generated by a current flowing through the inductor.
